(19) United States
(12) Patent Application Publication
(10) Pub. No.: US 2025/0391788 A1
(43) Pub. Date: Dec. 25, 2025

(54) SEMICONDUCTOR CHIP INCLUDING A CAPACITIVE SEAL RING ARCHITECTURE, AND METHOD FOR MANUFACTURING THE SAME

(71) Applicant: TAIWAN SEMICONDUCTOR MANUFACTURING COMPANY, LTD., Hsinchu (TW)

(72) Inventors: Chun-Hao LIN, Hsinchu (TW); Yu-Jen WANG, Hsinchu (TW); Chun-Hao CHOU, Hsinchu (TW)

(73) Assignee: TAIWAN SEMICONDUCTOR MANUFACTURING COMPANY, LTD., Hsinchu (TW)

(21) Appl. No.: 18/748,405

(22) Filed: Jun. 20, 2024

(51) Int. Cl. H01L 23/58; H01L 21/768; H01L 23/48; H01L 23/64

(52) U.S. Cl. CPC H01L 23/585; H01L 21/76898; H01L 23/481; H01L 23/642; H01L 2924/19041

(57) ABSTRACT

A semiconductor chip includes a first chip feature, and a second chip feature disposed on the first chip feature. The first chip feature includes a first substrate, a first seal ring disposed on the first substrate, a second seal ring disposed on the first substrate, and a first dielectric structure surrounding the first and second seal rings. The second chip feature includes a second substrate, a third seal ring disposed below the second substrate and connected to the first seal ring, a second dielectric structure surrounding the third seal ring, and a conductive ring formed in the second substrate and connected to the third seal ring. The second seal ring, a combination of the first and third seal rings, and a portion of the first dielectric structure and a portion of the second dielectric structure that are disposed between the second seal ring and the combination cooperatively constitute a capacitor.

### BACKGROUND

The semiconductor integrated circuit (IC) industry has, over the decades, experienced tremendous advancements and is still undergoing vigorous development. With dramatic advances in technology, the industry pays much attention on the development of small IC devices with high performance and low power consumption. Since substrate is an important component of a semiconductor device, substrate bonding issue, such as leakage issue, needs to be solved in order to facilitate the manufacturing process of semiconductor devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic top view of a semiconductor chip in accordance with some embodiments.

FIG. 2 is a schematic sectional view of a seal ring region of the semiconductor chip in accordance with some embodiments.

FIG. 3 is a schematic sectional view of a first seal ring and a second seal ring of the semiconductor chip in accordance with some embodiments.

FIG. 4 is a schematic sectional view of a seal ring region of the semiconductor chip in accordance with some embodiments.

FIG. 5 is a schematic sectional view of a seal ring region of the semiconductor chip in accordance with some embodiments.

FIG. 6 is a schematic sectional view of a seal ring region of the semiconductor chip in accordance with some embodiments.

FIG. 7 is a flow chart illustrating a method for manufacturing a semiconductor chip in accordance with some embodiments.

FIGS. 8 to 12 are schematic sectional views illustrating intermediate stages of a method for manufacturing a semiconductor chip in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “over,” “downwardly,” “upwardly,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly.

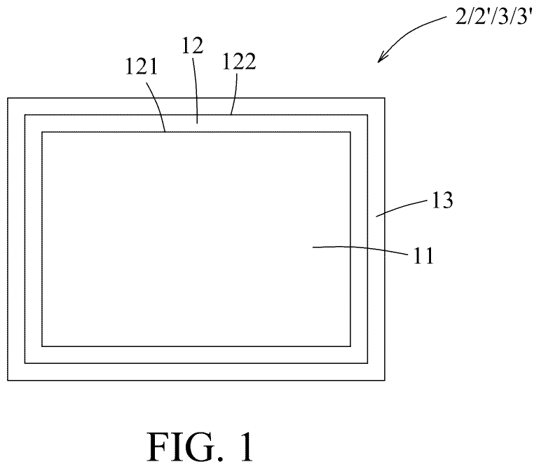

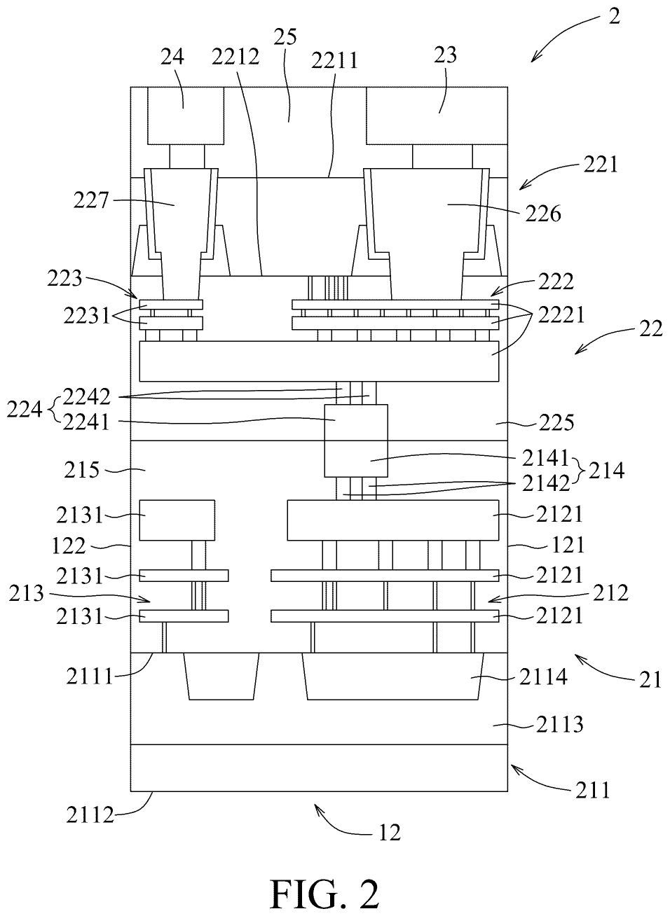

FIG. 1 is a schematic top view of a semiconductor chip in accordance with some embodiments. FIG. 2 is a schematic sectional view of a seal ring region of the semiconductor chip in accordance with some embodiments. Referring to FIGS. 1 and 2, the semiconductor chip 2 includes a circuit region 11, a seal ring region 12 that surrounds the circuit region 11, and a scribe line region 13 that surrounds the seal ring region 12. The seal ring region 12 has an inner boundary 121 that is adjacent to the circuit region 11, and an outer boundary 122 that is adjacent to the scribe line region 13. The semiconductor chip 2 includes a first chip feature 21, a second chip feature 22, a first connection feature 23, a second connection feature 24 and a dielectric feature 25.

The first chip feature 21 includes a first substrate 211, a first seal ring 212, a second seal ring 213, a first bonding element 214 and a first dielectric structure 215. The first substrate 211 extends throughout the circuit region 11, the seal ring region 12 and the scribe line region 13, has a top side 2111 (e.g., a front side) and a bottom side 2112 (e.g., a back side), and includes a well 2113 and an isolation element 2114. The well 2113 is formed in the first substrate 211 from the top side 2111 of the first substrate 211, is disposed in the seal ring region 12, has a ring shape (e.g., a continuous ring or a discontinuous ring (a ring that is broken at one or more places)), and encloses the circuit region 11. The isolation element 2114 (e.g., a shallow trench isolation (STI)) is formed in the well 2113 from the top side 2111 of the first substrate 211, has a ring shape (e.g., a continuous ring or a discontinuous ring), and encloses the circuit region 11. The first seal ring 212 is disposed on and connected to the isolation element 2114, and is close to the inner boundary 121 of the seal ring region 12. The second seal ring 213 is disposed on and connected to the well 2113, and is close to the outer boundary 122 of the seal ring region 12. The first bonding element 214 is disposed on and connected to the first seal ring 212, and includes a bonding link 2141 and at least one bonding connection 2142 (multiple bonding connections 2142 are depicted in FIG. 2). The bonding link 2141 is disposed over the first seal ring 212, has a ring shape (e.g., a continuous ring or a discontinuous ring), and encloses the circuit region 11. The at least one bonding connection 2142 interconnects the bonding link 2141 and the first seal ring 212, has a ring shape (e.g., a continuous ring or a discontinuous ring), and encloses the circuit region 11. The first dielectric structure 215 is disposed on the top side 2111 of the first substrate 211, extends throughout the circuit region 11, the seal ring region 12 and the scribe line region 13, and surrounds the first seal ring 212, the second seal ring 213 and the first bonding element 214.

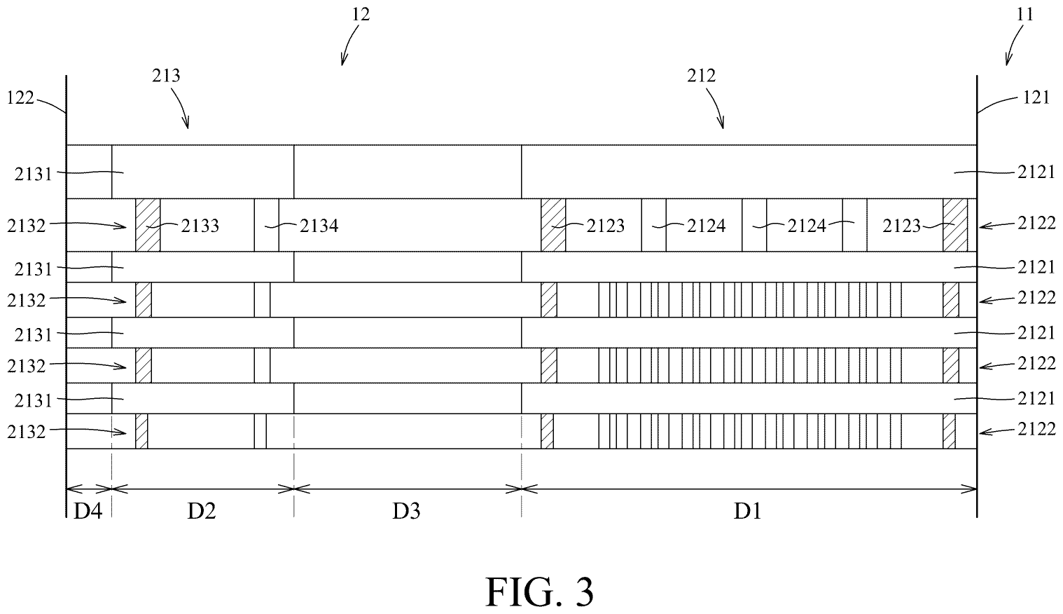

FIG. 3 is a schematic sectional view of a first seal ring and a second seal ring of the semiconductor chip in accordance with some embodiments. Referring to FIG. 3, the first seal ring 212 includes a plurality of ring features 2121 and a plurality of interconnection features 2122. The ring features 2121 are arranged from bottom to top, have the same width of D1 (e.g., about 5 μm), and are, for example, immediately adjacent to (e.g., connected to) the inner boundary 121 of the seal ring region 12. Each of the ring features 2121 has a ring shape (e.g., a continuous ring or a discontinuous ring), and encloses the circuit region 11. Each of the interconnection features 2122 includes two first contact vias 2123 and a plurality of second contact vias 2124. With respect to each of the interconnection features 2122, the first contact vias 2123 and the second contact vias 2124 either interconnect a bottommost one of the ring features 2121 and the isolation element 2114 (see FIG. 2), or interconnect two adjacent ones of the ring features 2121. With respect to each of the interconnection features 2122, each of the first contact vias 2123 has a ring shape (e.g., a continuous ring or a discontinuous ring), and encloses the circuit region 11, and the second contact vias 2124 each have a polygonal or circular shape (as opposed to ring shape), and are disposed between the first contact vias 2123. The second seal ring 213 includes a plurality of ring features 2131 and a plurality of interconnection features 2132. The ring features 2131 are arranged from bottom to top, have the same width of D2 (e.g., about 2 μm), are spaced apart from the ring features 2121 by a distance of D3 (e.g., about 2.5 μm), and are spaced apart from the outer boundary 122 of the seal ring region 12 by a distance of D4 (e.g., 0.5 μm). Each of the ring features 2131 has a ring shape (e.g., a continuous ring or a discontinuous ring), and encloses the circuit region 11. Each of the interconnection features 2132 includes a contact via 2133 and a plurality of second contact vias 2134. With respect to each of the interconnection features 2132, the first contact via 2133 and the second contact vias 2134 either interconnect a bottommost one of the ring features 2131 and the well 2113 (see FIG. 2), or interconnect two adjacent ones of the ring features 2131. With respect to each of the interconnection features 2132, the first contact via 2133 has a ring shape (e.g., a continuous ring or a discontinuous ring), and encloses the circuit region 11, and the second contact vias 2134 each have a polygonal or circular shape (as opposed to ring shape), and are enclosed by the first contact via 2133.

Referring back to FIGS. 1 and 2, the second chip feature 22 is disposed on the first chip feature 21, and includes a second substrate 221, a third seal ring 222, a fourth seal ring 223, a second bonding element 224, a second dielectric structure 225, a first conductive ring 226 and a second conductive ring 227. The second substrate 221 extends throughout the circuit region 11, the seal ring region 12 and the scribe line region 13, and has a top side 2211 (e.g., a back side) and a bottom side 2212 (e.g., a front side). The third seal ring 222 is disposed in the seal ring region 12 and below the bottom side 2212 of the second substrate 221, and is close to the inner boundary 121 of the seal ring region 12. The third seal ring 222 includes a plurality of ring features 2221 and a plurality of interconnection features (not labeled). The third seal ring 222 is similar in structure to the first seal ring 212 depicted in FIG. 3, but, unlike the first seal ring 212 depicted in FIG. 3 where all ring features 2121 of the first seal ring 212 have the same width, for the third seal ring 222, a bottommost one of the ring features 2221 is wider than the other ones of the ring features 2221. The fourth seal ring 223 is disposed in the seal ring region 12, below the bottom side 2212 of the second substrate 221 and above the bottommost one of the ring features 2221, is close to the outer boundary 122 of the seal ring region 12, and is connected to the bottommost one of the ring features 2221. The fourth seal ring 223 includes a plurality of ring features 2231 and a plurality of interconnection features (not labeled), and is similar in structure to the second seal ring 213 depicted in FIG. 3. The second bonding element 224 is disposed below and connected to the third seal ring 222, and includes a bonding link 2241 and at least one bonding connection 2242 (multiple bonding connections 2242 are depicted in FIG. 2). The bonding link 2241 is disposed below the third seal ring 222, is bonded to the bonding link 2141 of the first bonding element 214, has a ring shape (e.g., a continuous ring or a discontinuous ring), and encloses the circuit region 11. The at least one bonding connection 2242 interconnects the bonding link 2241 and the third seal ring 222, has a ring shape (e.g., a continuous ring or a discontinuous ring), and encloses the circuit region 11. The second dielectric structure 225 is disposed below the bottom side 2212 of the second substrate 221, extends throughout the circuit region 11, the seal ring region 12 and the scribe line region 13, surrounds the third seal ring 222, the fourth seal ring 223 and the second bonding element 224, and is bonded to the first dielectric structure 215. The first conductive ring 226 (e.g., a continuous ring or a discontinuous ring) is formed in the second substrate 221 and the second dielectric structure 225 from the top side 2211 of the second substrate 221, is disposed on and connected to the third seal ring 222, and encloses the circuit region 11. The second conductive ring 227 (e.g., a continuous ring or a discontinuous ring) is formed in the second substrate 221 and the second dielectric structure 225 from the top side 2211 of the second substrate 221, is disposed on and connected to the fourth seal ring 223, and encloses the circuit region 11.

The first connection feature 23 is disposed on and connected to the first conductive ring 226, and the second connection feature 24 is disposed on and connected to the second conductive ring 227. The dielectric feature 25 is disposed on the top side 2211 of the second substrate 221, extends throughout the circuit region 11, the seal ring region 12 and the scribe line region 13, and surrounds the first connection feature 23 and the second connection feature 24.

The bottommost one of the ring features 2221 of the third seal ring 222 partially overlaps a topmost one of the ring features 2131 of the second seal ring 213. A combination of the first seal ring 212, the first bonding element 214, the second bonding element 224 and the third seal ring 222, the second seal ring 213, and a portion of the first dielectric structure 215 and a portion of the second dielectric structure 225 that are disposed between the combination and the second seal ring 213 cooperatively constitute a capacitor. The well 2113 and the first connection feature 23 may be biased to different voltages (e.g., one of the well 2113 and the first connection feature 23 is biased to a ground voltage, and the other one of the well 2113 and the first connection feature 23 is biased to a voltage that is higher than or lower than the ground voltage), so a voltage across the capacitor is non-zero.

In some embodiments, a spacing between the bottommost one of the ring features 2221 and the topmost one of the ring features 2131 may fall within a range of from about 2 μm to about 5 μm, a width of the topmost one of the ring features 2131 may fall within a range of from about 2 μm to about 5 μm, and a length of the topmost one of the ring features 2131 may fall within a range of from about 104 μm to about 106 μm, so the capacitor can reach its target capacitance.

In some embodiments, the first conductive ring 226 and the second conductive ring 227 may be formed using a process for forming a backside through silicon via, and may be made of, for example, copper; and the first connection feature 23 and the second connection feature 24 may be formed using a process for forming a backside pad, and may be made of, for example, aluminum copper.

In some embodiments, the first conductive ring 226 and the second conductive ring 227 may be formed using a process for forming a backside pad, and may be made of, for example, aluminum copper; and the first connection feature 23 and the second connection feature 24 may be omitted.

In some embodiments, devices such as transistors, resistors, capacitors, etc., may be formed in the circuit region 11.

By virtue of a combination of the first conductive ring 226, the third seal ring 222, the second bonding element 224, the first bonding element 214 and the first seal ring 212, where the combination is formed in the seal ring region 12 of the semiconductor chip 2, leakage and power consumption of the semiconductor chip 2 can be reduced, and introduction of die-sawing stress, contaminants and moisture into the circuit region 11 can be prevented. In addition, by virtue of the capacitor formed in the seal ring region 12 of the semiconductor chip 2, leakage and power consumption of the semiconductor chip 2 can be further reduced.

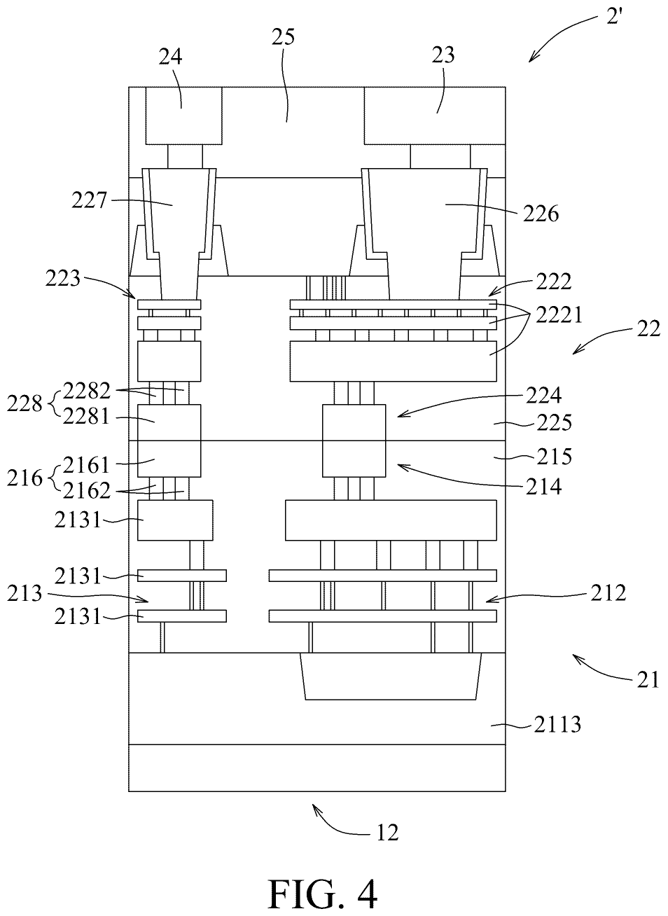

FIG. 4 is a schematic sectional view of a seal ring region of the semiconductor chip in accordance with some embodiments. Referring to FIGS. 1 and 4, the semiconductor chip 2′ depicted in FIG. 4 is similar to the semiconductor chip 2 depicted in FIG. 2, but differs from the semiconductor chip 2 depicted in FIG. 2 in what will be described below. In the semiconductor chip 2′ depicted in FIG. 4, the first chip feature 21 further includes a bonding element 216. The bonding element 216 is disposed on and connected to the second seal ring 213, is surrounded by the first dielectric structure 215, and includes a bonding link 2161 and at least one bonding connection 2162 (multiple bonding connections 2162 are depicted in FIG. 4). The bonding link 2161 is disposed over the second seal ring 213, has a ring shape (e.g., a continuous ring or a discontinuous ring), and encloses the circuit region 11. The at least one bonding connection 2162 interconnects the bonding link 2161 and the second seal ring 213, has a ring shape (e.g., a continuous ring or a discontinuous ring), and encloses the circuit region 11. The bottommost one of the ring features 2221 is not wider than the other ones of the ring features 2221, and is non-overlapping with the topmost one of the ring features 2131. The second chip feature 22 further includes a bonding element 228. The bonding element 228 is disposed below and connected to the fourth seal ring 223, is surrounded by the second dielectric structure 225, and includes a bonding link 2281 and at least one bonding connection 2282 (multiple bonding connections 2282 are depicted in FIG. 4). The bonding link 2281 is disposed below the fourth seal ring 223, has a ring shape (e.g., a continuous ring or a discontinuous ring), and encloses the circuit region 11. The at least one bonding connection 2282 interconnects the bonding link 2281 and the fourth seal ring 223, has a ring shape (e.g., a continuous ring or a discontinuous ring), and encloses the circuit region 11. Each of the first connection feature 23 and the second connection feature 24 has a ring shape (e.g., a continuous ring or a discontinuous ring), and encloses the circuit region 11. A combination of the first seal ring 212, the first bonding element 214, the second bonding element 224, the third seal ring 222, the first conductive ring 226 and the first connection feature 23 (hereinafter referred to as “the first combination”), a combination of the second seal ring 213, the bonding elements 216, 228, the fourth seal ring 223, the second conductive ring 227 and the second connection feature 24 (hereinafter referred to as “the second combination”), and a portion of the first dielectric structure 215, a portion of the second dielectric structure 225 and a portion of the dielectric feature 25 that are disposed between the first combination and the second combination cooperatively constitute a capacitor. The well 2113 and the first connection feature 23 may be biased to different voltages (e.g., one of the well 2113 and the first connection feature 23 is biased to the ground voltage, and the other one of the well 2113 and the first connection feature 23 is biased to a voltage that is higher than or lower than the ground voltage), so a voltage across the capacitor is non-zero.

In some embodiments, an effective spacing between the first combination and the second combination may fall within a range of from about 2 μm to about 5 μm, a height of each of the first combination and the second combination may fall within a range of from about 2 μm to about 10 μm, and an average of an effective length of the first combination and an effective length of the second combination may fall within a range of from about 104 μm to about 106 μm, so the capacitor can reach its target capacitance.

In some embodiments, the first conductive ring 226 and the second conductive ring 227 may be formed using a process for forming a backside through silicon via, and may be made of, for example, copper; and the first connection feature 23 and the second connection feature 24 may be formed using a process for forming a backside pad, and may be made of, for example, aluminum copper.

In some embodiments, the first conductive ring 226 and the second conductive ring 227 may be formed using a process for forming a backside pad, and may be made of, for example, aluminum copper; and the first connection feature 23 and the second connection feature 24 may be omitted.

By virtue of a combination of the first conductive ring 226, the third seal ring 222, the second bonding element 224, the first bonding element 214 and the first seal ring 212, where the combination is formed in the seal ring region 12 of the semiconductor chip 2′, leakage and power consumption of the semiconductor chip 2′ can be reduced, and introduction of die-sawing stress, contaminants and moisture into the circuit region 11 can be prevented. In addition, by virtue of the capacitor formed in the seal ring region 12 of the semiconductor chip 2′, leakage and power consumption of the semiconductor chip 2′ can be further reduced.

It should be noted that, in some embodiments, the semiconductor chip may include more than two chip features (e.g., three chip features), and a capacitor may be formed in the seal ring region of the semiconductor chip to reduce leakage and power consumption of the semiconductor chip.

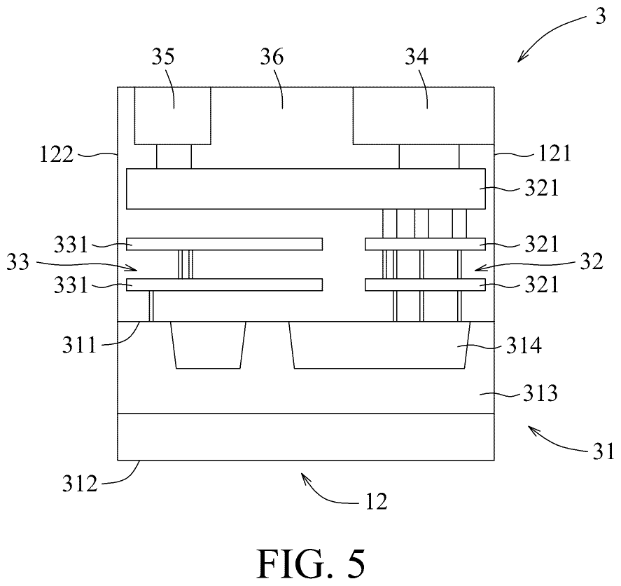

FIG. 5 is a schematic sectional view of a seal ring region of the semiconductor chip in accordance with some embodiments. Referring to FIGS. 1 and 5, the semiconductor chip 3 includes a circuit region 11, a seal ring region 12 that surrounds the circuit region 11, and a scribe line region 13 that surrounds the seal ring region 12. The seal ring region 12 has an inner boundary 121 that is adjacent to the circuit region 11, and an outer boundary 122 that is adjacent to the scribe line region 13. The semiconductor chip 3 includes a substrate 31, a first seal ring 32, a second seal ring 33, a first connection feature 34, a second connection feature 35 and a dielectric structure 36. The substrate 31 extends throughout the circuit region 11, the seal ring region 12 and the scribe line region 13, has a top side 311 (e.g., a front side) and a bottom side 312 (e.g., a back side), and includes a well 313 and an isolation element 314. The well 313 is formed in the substrate 31 from the top side 311 of the substrate 31, is disposed in the seal ring region 12, has a ring shape (e.g., a continuous ring or a discontinuous ring), and encloses the circuit region 11. The isolation element 314 (e.g., a shallow trench isolation (STI)) is formed in the well 313 from the top side 311 of the substrate 31, has a ring shape (e.g., a continuous ring or a discontinuous ring), and encloses the circuit region 11. The first seal ring 32 is disposed on and connected to the isolation element 314, is close to the inner boundary 121 of the seal ring region 12, includes a plurality of ring features 321 and a plurality of interconnection features (not labeled), and is similar in structure to the first seal ring 212 depicted in FIG. 3. The second seal ring 33 is disposed on and connected to the well 313, is close to the outer boundary 122 of the seal ring region 12, includes a plurality of ring features 331 and a plurality of interconnection features (not labeled), and is similar in structure to the second seal ring 213 depicted in FIG. 3. The first connection feature 34 is disposed on and connected to the first seal ring 32, and is close to the inner boundary 121 of the seal ring region 12. The second connection feature 35 is disposed on and connected to the first seal ring 32, and is close to the outer boundary 122 of the seal ring region 12. The dielectric structure 36 is disposed on the top side 311 of the substrate 31, extends throughout the circuit region 11, the seal ring region 12 and the scribe line region 13, and surrounds the first seal ring 32, the second seal ring 33, the first connection feature 34 and the second connection feature 35.

A topmost one of the ring features 321 of the first seal ring 32 is wider than the other ones of the ring features 321 of the first seal ring 32, is higher than a topmost one of the ring features 331 of the second seal ring 33, and partially overlaps the topmost one of the ring features 331 of the second seal ring 33. The first seal ring 32, the second seal ring 33, and a portion of the dielectric structure 36 that is disposed between the first seal ring 32 and the second seal ring 33 cooperatively constitute a capacitor. The well 313 and the first connection feature 34 may be biased to different voltages (e.g., one of the well 313 and the first connection feature 34 is biased to the ground voltage, and the other one of the well 313 and the first connection feature 34 is biased to a voltage that is higher than or lower than the ground voltage), so a voltage across the capacitor is non-zero.

In some embodiments, a spacing between the topmost one of the ring features 321 of the first seal ring 32 and the topmost one of the ring features 331 of the second seal ring 33 may fall within a range of from about 0.01 μm to about 5 μm, and a width of the topmost one of the ring features 331 may fall within a range of from about 2 μm to about 5 μm, so the capacitor can reach its target capacitance.

In some embodiments, the first connection feature 34 and the second connection feature 35 may be formed using a process for forming a pad, and may be made of, for example, aluminum copper.

By virtue of the capacitor formed in the seal ring region 12 of the semiconductor chip 3, leakage and power consumption of the semiconductor chip 3 can be reduced.

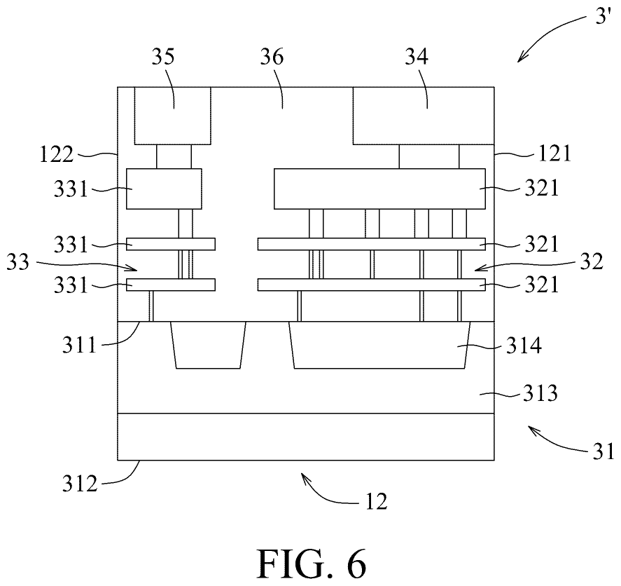

FIG. 6 is a schematic sectional view of a seal ring region of the semiconductor chip in accordance with some embodiments. Referring to FIGS. 1 and 6, the semiconductor chip 3′ depicted in FIG. 6 is similar to the semiconductor chip 3 depicted in FIG. 5, but differs from the semiconductor chip 3 depicted in FIG. 5 in what will be described below. In the semiconductor chip 3′ depicted in FIG. 6, the topmost one of the ring features 321 of the first seal ring 32 is not wider than the other ones of the ring features 321 of the first seal ring 32, and is non-overlapping with the topmost one of the ring features 331 of the second seal ring 33 in a direction from bottom to top of the semiconductor chip 3′. Each of the first connection feature 34 and the second connection feature 35 has a ring shape (e.g., a continuous ring or a discontinuous ring), and encloses the circuit region 11. A combination of the first seal ring 32 and the first connection feature 34 (hereinafter referred to as “the first combination”), a combination of the second seal ring 33 and the second connection feature 35 (hereinafter referred to as “the second combination”), and a portion of the dielectric structure 36 that is disposed between the first combination and the second combination cooperatively constitute a capacitor. The well 313 and the first connection feature 34 may be biased to different voltages (e.g., one of the well 313 and the first connection feature 34 is biased to the ground voltage, and the other one of the well 313 and the first connection feature 34 is biased to a voltage that is higher than or lower than the ground voltage), so a voltage across the capacitor is non-zero.

In some embodiments, an effective spacing between the first combination and the second combination may fall within a range of from about 2 μm to about 5 μm, and a height of each of the first combination and the second combination may fall within a range of about 2 μm to about 5 μm, so the capacitor can reach its target capacitance.

In some embodiments, the first connection feature 34 and the second connection feature 35 may be formed using a process for forming a pad, and may be made of, for example, aluminum copper.

By virtue of the capacitor formed in the seal ring region 12 of the semiconductor chip 3′, leakage and power consumption of the semiconductor chip 3′ can be reduced.

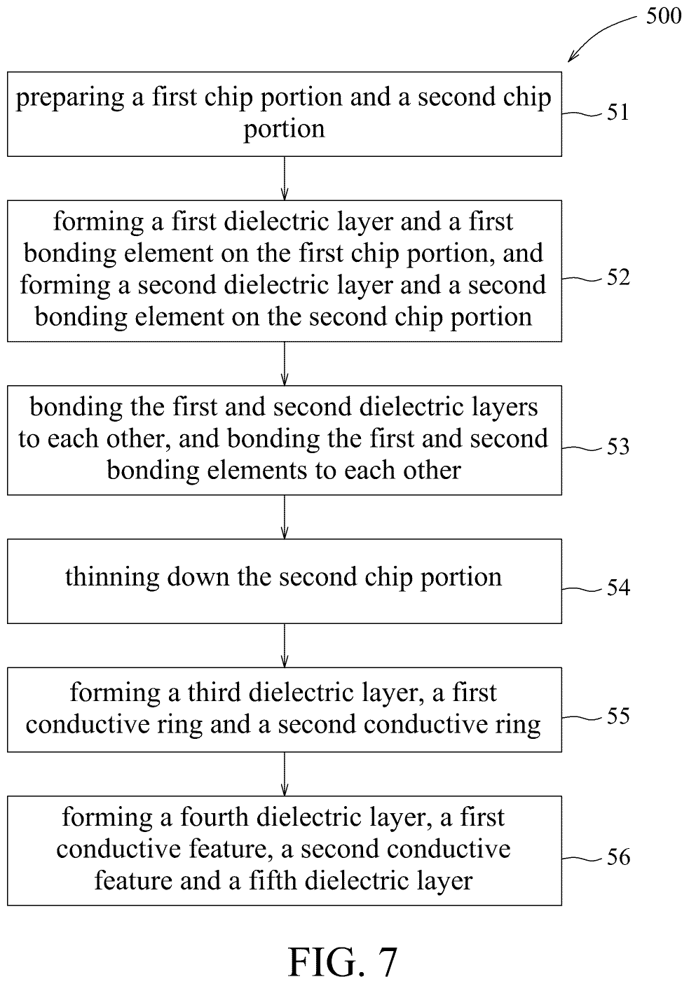

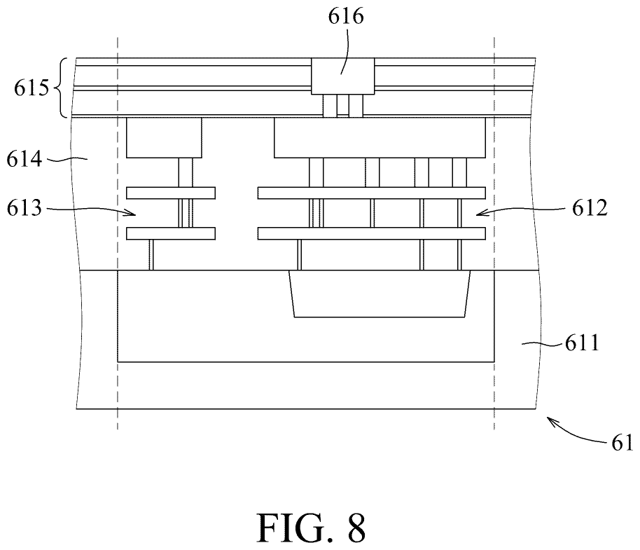

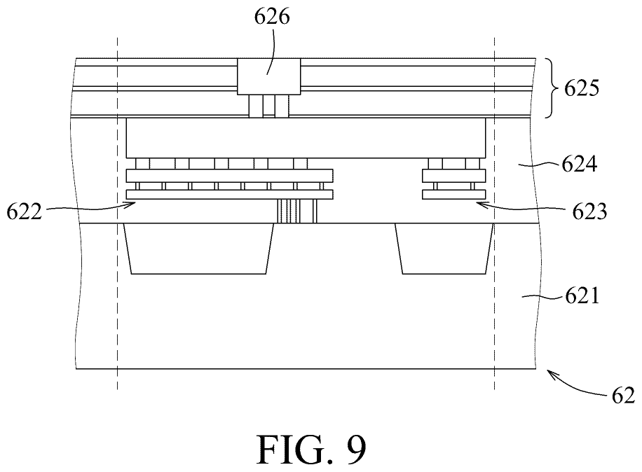

FIG. 7 is a flow chart illustrating a method 500 for manufacturing a semiconductor chip in accordance with some embodiments. FIGS. 8 to 12 are schematic sectional views of semiconductor structures 600 during various stages of the method 500. The method 500 and the semiconductor structures 600 will be described together below. It should be noted that additional steps can be provided before, after or during the method 500, and some of the steps described herein may be replaced by other steps or be eliminated. Similarly, further additional features may be present in the semiconductor structures 600, and/or features present may be replaced or eliminated in additional embodiments.

Referring to FIGS. 7 to 9, the method 500 begins at step 51, where a first chip portion 61 and a second chip portion 62 are prepared. The first chip portion 61 includes a first substrate 611, a first seal ring 612 and a second seal ring 613 that would respectively serve as the first substrate 211, the first seal ring 212 and the second seal ring 213 of the semiconductor chip 2 depicted in FIG. 2, and further includes a first interlayer dielectric 614. The second chip portion 62 includes a second substrate 621, a third seal ring 622 and a fourth seal ring 623 that would respectively serve as the second substrate 221, the third seal ring 222 and the fourth seal ring 223 of the semiconductor chip 2 depicted in FIG. 2, and further includes a second interlayer dielectric 624.

The method 500 then proceeds to step 52, where a first dielectric layer 615 and a second dielectric layer 625 are respectively formed on the first chip portion 61 and the second chip portion 62, and then a first bonding element 616 and a second bonding element 626 are respectively formed in the first dielectric layer 615 and the second dielectric layer 625. A combination of the first interlayer dielectric 614 and the first dielectric layer 615 would serve as the first dielectric structure 215 of the semiconductor chip 2 depicted in FIG. 2. A combination of the second interlayer dielectric 624 and the second dielectric layer 625 would serve as the second dielectric structure 225 of the semiconductor chip 2 depicted in FIG. 2. The first bonding element 616 and the second bonding element 626 would respectively serve as the first bonding element 214 and the second bonding element 224 of the semiconductor chip 2 depicted in FIG. 2.

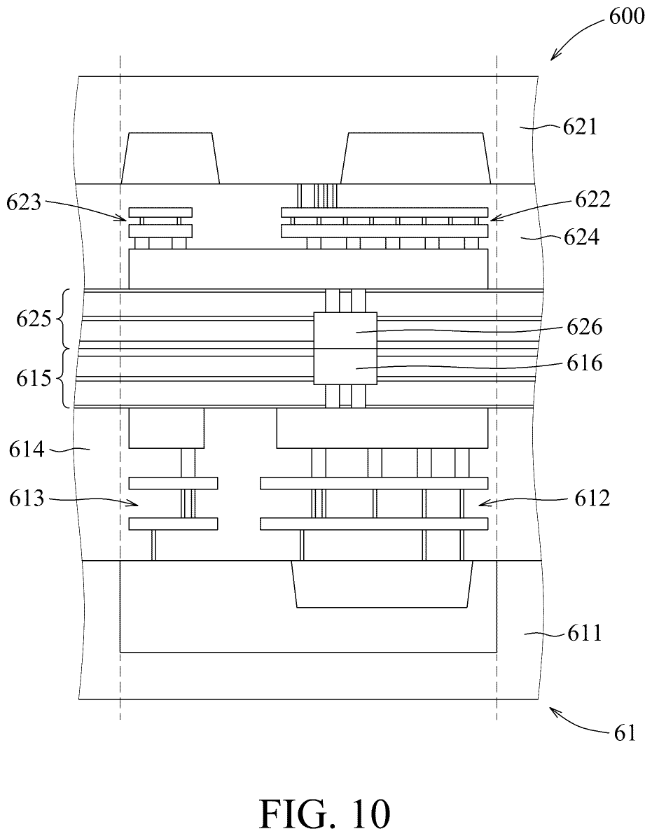

Referring to FIGS. 7 and 10, the method 500 then proceeds to step 53, where the first dielectric layer 615 and the second dielectric layer 625 are bonded to each other, and the first bonding element 616 and the second bonding element 626 are bonded to each other.

The method 500 then proceeds to step 54, where the second substrate 621 is thinned down.

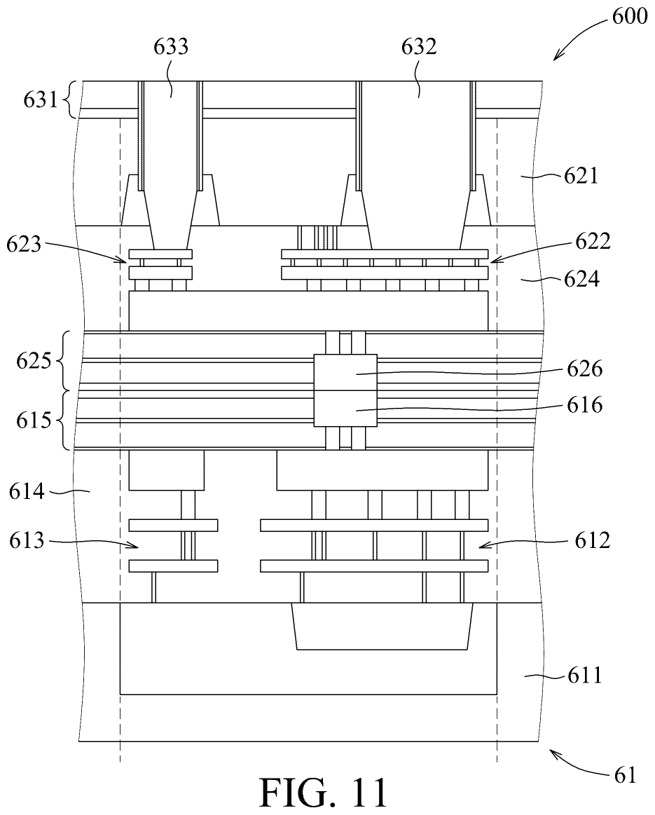

Referring to FIGS. 7 and 11, the method 500 then proceeds to step 55, where a third dielectric layer 631 is formed on the second substrate 621, and then a first conductive ring 632 and a second conductive ring 633 are formed in the third dielectric layer 631, the second substrate 621 and the second interlayer dielectric 624. The first conductive ring 632 and the second conductive ring 633 would respectively serve as the first conductive ring 226 and the second conductive ring 227 of the semiconductor chip 2 depicted in FIG. 2.

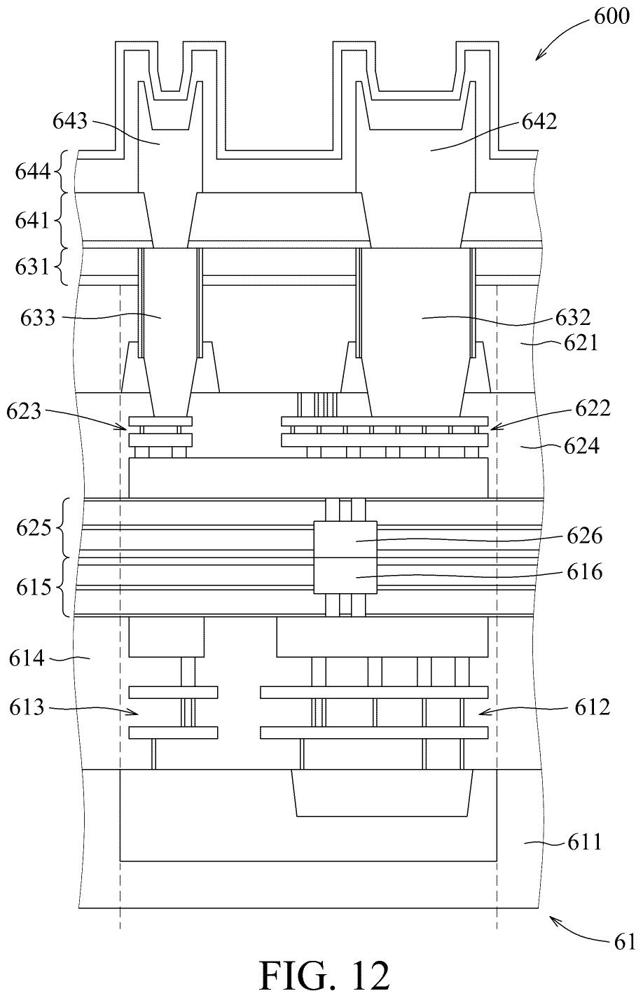

Referring to FIGS. 7 and 12, the method 500 then proceeds to step 56, where a fourth dielectric layer 641 is formed on the third dielectric layer 631, the first conductive ring 632 and the second conductive ring 633, then a first connection feature 642 and a second connection feature 643 are formed in the fourth dielectric layer 641, and finally a fifth dielectric layer 644 is formed on the fourth dielectric layer 641, the first connection feature 642 and the second connection feature 643. The first connection feature 642 and the second connection feature 643 would respectively serve as the first connection feature 23 and the second connection feature 24 of the semiconductor chip 2 depicted in FIG. 2. A combination of the fourth dielectric layer 641 and the fifth dielectric layer 644 would serve as the dielectric feature 25 of the semiconductor chip 2 depicted in FIG. 2.

In accordance with some embodiments of the present disclosure, a semiconductor chip includes a circuit region and a seal ring region that surrounds the circuit region, and includes a first chip feature and a second chip feature. The first chip feature includes a first substrate, a first seal ring, a second seal ring, a first bonding element and a first dielectric structure. The first substrate has a top side and a bottom side, and includes a well which is formed from the top side of the first substrate and which is formed in the seal ring region, and an isolation element which is formed in the well from the top side of the first substrate. The first seal ring is disposed on and connected to the isolation element, and is close to an inner boundary of the seal ring region. The second seal ring is disposed on and connected to the well, and is close to an outer boundary of the seal ring region. The first bonding element is disposed on and connected to the first seal ring. The first dielectric structure is disposed on the top side of the first substrate, and surrounds the first seal ring, the second seal ring and the first bonding element. The second chip feature is disposed on the first chip feature, and includes a second substrate, a third seal ring, a second bonding element, a second dielectric structure and a first conductive ring. The second substrate has a top side and a bottom side. The third seal ring is disposed in the seal ring region and below the bottom side of the second substrate. The second bonding element is disposed below and connected to the third seal ring, and is bonded to the first bonding element. The second dielectric structure is disposed below the bottom side of the second substrate, surrounds the third seal ring and the second bonding element, and is bonded to the first dielectric structure. The first conductive ring is formed in the second substrate and the second dielectric structure from the top side of the second substrate, and is disposed on and connected to the third seal ring. At least the second seal ring, a first combination of the third seal ring, the second bonding element, the first bonding element and the first seal ring, and a portion of the first dielectric structure and a portion of the second dielectric structure that are disposed between the second seal ring and the first combination cooperatively constitute a capacitor.

In accordance with some embodiments of the present disclosure, each of the second seal ring and the third seal ring includes a plurality of ring features that are arranged from bottom to top; and a bottommost one of the ring features of the third seal ring partially overlaps a topmost one of the ring features of the second seal ring.

In accordance with some embodiments of the present disclosure, a spacing between the bottommost one of the ring features of the third seal ring and the topmost one of the ring features of the second seal ring falls within a range of from 2 μm to 5 μm.

In accordance with some embodiments of the present disclosure, the third seal ring is close to the inner boundary of the seal ring region; and the second chip feature further includes a fourth seal ring that is disposed in the seal ring region, that is below the bottom side of the second substrate and above the bottommost one of the ring features of the third seal ring, that is close to the outer boundary of the seal ring region, and that is connected to the bottommost one of the ring features of the third seal ring.

In accordance with some embodiments of the present disclosure, the second chip feature further includes a second conductive ring that is formed in the second substrate and the second dielectric structure from the top side of the second substrate, and that is disposed on and connected to the fourth seal ring.

In accordance with some embodiments of the present disclosure, the first conductive ring is formed using a process for forming a backside pad.

In accordance with some embodiments of the present disclosure, the first conductive ring is formed using a process for forming a backside through silicon via.

In accordance with some embodiments of the present disclosure, the semiconductor chip further includes a connection feature that is disposed on and connected to the first conductive ring.

In accordance with some embodiments of the present disclosure, the well and the first conductive ring are to be biased to different voltages.

In accordance with some embodiments of the present disclosure, the first chip feature further includes a third bonding element. The third bonding element is disposed on and connected to the second seal ring, and is surrounded by the first dielectric structure. The second chip feature further includes a fourth seal ring, a fourth bonding element and a second conductive ring. The fourth seal ring is disposed in the seal ring region and below the bottom side of the second substrate, is surrounded by the second dielectric structure, and is close to the outer boundary of the seal ring region. The fourth bonding element is disposed below and connected to the fourth seal ring, is surrounded by the second dielectric structure, and is bonded to the third bonding element. The second conductive ring is formed in the second substrate and the second dielectric structure from the top side of the second substrate, and is disposed on and connected to the fourth seal ring. The first combination further includes the first conductive ring. The first combination, a second combination of the second seal ring, the third bonding element, the fourth bonding element, the fourth seal ring and the second conductive ring, and a portion of the first dielectric structure and a portion of the second dielectric structure that are disposed between the first combination and the second combination cooperatively constitute the capacitor.

In accordance with some embodiments of the present disclosure, the first conductive ring and the second conductive ring are formed using a process for forming a backside pad.

In accordance with some embodiments of the present disclosure, the first conductive ring and the second conductive ring are formed using a process for forming a backside through silicon via.

In accordance with some embodiments of the present disclosure, an effective spacing between the first combination and the second combination falls within a range of from 2 μm to 5 μm.

In accordance with some embodiments of the present disclosure, a semiconductor chip includes a circuit region and a seal ring region that surrounds the circuit region, and includes a substrate, a first seal ring, a second seal ring, a first connection feature and a dielectric structure. The substrate has a top side and a bottom side, and includes a well that is formed from the top side of the substrate and that is in the seal ring region, and an isolation element that is formed in the well from the top side of the substrate. The first seal ring is disposed on and connected to the isolation element, and is close to an inner boundary of the seal ring region. The second seal ring is disposed on and connected to the well, and is close to an outer boundary of the seal ring region. The first connection feature is disposed on and connected to the first seal ring. The dielectric structure is disposed on the top side of the substrate, and surrounds the first seal ring, the second seal ring and the first connection feature. At least the first seal ring, the second seal ring, and a portion of the dielectric structure that is disposed between the first seal ring and the second seal ring cooperatively constitute a capacitor.

In accordance with some embodiments of the present disclosure, each of the first seal ring and the second seal ring includes a plurality of ring features that are arranged from bottom to top; and a topmost one of the ring features of the first seal ring is higher than a topmost one of the ring features of the second seal ring, and partially overlaps the topmost one of the ring features of the second seal ring.

In accordance with some embodiments of the present disclosure, a spacing between the topmost one of the ring features of the first seal ring and the topmost one of the ring features of the second seal ring falls within a range of from 0.01 μm to 5 μm.

In accordance with some embodiments of the present disclosure, the semiconductor chip further includes a second connection feature that is disposed on and connected to the second seal ring, and that is surrounded by the dielectric structure. A first combination of the first seal ring and the first connection feature, a second combination of the second seal ring and the second connection feature, and a portion of the dielectric structure that is disposed between the first combination and the second combination cooperatively constitute the capacitor.

In accordance with some embodiments of the present disclosure, an effective spacing between the first combination and the second combination falls within a range of from 2 μm to 5 μm.

In accordance with some embodiments of the present disclosure, a method for manufacturing a semiconductor chip includes: preparing a first chip portion that includes a first substrate, a first seal ring disposed on the first substrate, a second seal ring disposed on the first substrate, and a first interlayer dielectric disposed on the first substrate and surrounding the first seal ring and the second seal ring; forming a first dielectric layer and a first bonding element on the first chip portion, where the first bonding element is connected to the first seal ring and is surrounded by the first dielectric layer; preparing a second chip portion that includes a second substrate, a third seal ring disposed on the second substrate, and a second interlayer dielectric disposed on the second substrate and surrounding the third seal ring; forming a second dielectric layer and a second bonding element on the second chip portion, where the second bonding element is connected to the third seal ring and is surrounded by the second dielectric layer; bonding the first dielectric layer and the second dielectric layer to each other, and bonding the first bonding element and the second bonding element to each other; and forming a conductive ring in the second substrate and the second interlayer dielectric, where the conductive ring is connected to the third seal ring.

In accordance with some embodiments of the present disclosure, the method further includes thinning down the second substrate before the conductive ring is formed.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor chip including a circuit region and a seal ring region that surrounds the circuit region, and comprising:
a first chip feature including
a first substrate that has a top side and a bottom side, and that includes a well which is formed from the top side of the first substrate and which is formed in the seal ring region, and an isolation element which is formed in the well from the top side of the first substrate,
a first seal ring that is disposed on and connected to the isolation element, and that is close to an inner boundary of the seal ring region,
a second seal ring that is disposed on and connected to the well, and that is close to an outer boundary of the seal ring region,
a first bonding element that is disposed on and connected to the first seal ring, and
a first dielectric structure that is disposed on the top side of the first substrate, and that surrounds the first seal ring, the second seal ring and the first bonding element; and
a second chip feature disposed on the first chip feature, and including
a second substrate that has a top side and a bottom side,
a third seal ring that is disposed in the seal ring region and below the bottom side of the second substrate,
a second bonding element that is disposed below and connected to the third seal ring, and that is bonded to the first bonding element,
a second dielectric structure that is disposed below the bottom side of the second substrate, that surrounds the third seal ring and the second bonding element, and that is bonded to the first dielectric structure, and
a first conductive ring that is formed in the second substrate and the second dielectric structure from the top side of the second substrate, and that is disposed on and connected to the third seal ring;
wherein at least the second seal ring, a first combination of the third seal ring, the second bonding element, the first bonding element and the first seal ring, and a portion of the first dielectric structure and a portion of the second dielectric structure that are disposed between the second seal ring and the first combination cooperatively constitute a capacitor.

2. The semiconductor chip according to claim 1, wherein:
each of the second seal ring and the third seal ring includes a plurality of ring features that are arranged from bottom to top; and
a bottommost one of the ring features of the third seal ring partially overlaps a topmost one of the ring features of the second seal ring.

3. The semiconductor chip according to claim 2, wherein a spacing between the bottommost one of the ring features of the third seal ring and the topmost one of the ring features of the second seal ring falls within a range of from 2 μm to 5 μm.

4. The semiconductor chip according to claim 2, wherein:
the third seal ring is close to the inner boundary of the seal ring region; and
the second chip feature further includes a fourth seal ring that is disposed in the seal ring region, that is below the bottom side of the second substrate and above the bottommost one of the ring features of the third seal ring, that is close to the outer boundary of the seal ring region, and that is connected to the bottommost one of the ring features of the third seal ring.

5. The semiconductor chip according to claim 4, wherein the second chip feature further includes a second conductive ring that is formed in the second substrate and the second dielectric structure from the top side of the second substrate, and that is disposed on and connected to the fourth seal ring.

6. The semiconductor chip according to claim 1, wherein the first conductive ring is formed using a process for forming a backside pad.

7. The semiconductor chip according to claim 1, wherein the first conductive ring is formed using a process for forming a backside through silicon via.

8. The semiconductor chip according to claim 7, further comprising a connection feature that is disposed on and connected to the first conductive ring.

9. The semiconductor chip according to claim 1, wherein the well and the first conductive ring are to be biased to different voltages.

10. The semiconductor chip according to claim 1, wherein:
the first chip feature further includes
a third bonding element that is disposed on and connected to the second seal ring, and that is surrounded by the first dielectric structure;
the second chip feature further includes
a fourth seal ring that is disposed in the seal ring region and below the bottom side of the second substrate, that is surrounded by the second dielectric structure, and that is close to the outer boundary of the seal ring region,
a fourth bonding element that is disposed below and connected to the fourth seal ring, that is surrounded by the second dielectric structure, and that is bonded to the third bonding element, and
a second conductive ring that is formed in the second substrate and the second dielectric structure from the top side of the second substrate, and that is disposed on and connected to the fourth seal ring;
the first combination further includes the first conductive ring; and
the first combination, a second combination of the second seal ring, the third bonding element, the fourth bonding element, the fourth seal ring and the second conductive ring, and a portion of the first dielectric structure and a portion of the second dielectric structure that are disposed between the first combination and the second combination cooperatively constitute the capacitor.

11. The semiconductor chip according to claim 10, wherein the first conductive ring and the second conductive ring are formed using a process for forming a backside pad.

12. The semiconductor chip according to claim 10, wherein the first conductive ring and the second conductive ring are formed using a process for forming a backside through silicon via.

13. The semiconductor chip according to claim 10, wherein an effective spacing between the first combination and the second combination falls within a range of from 2 μm to 5 μm.

14. A semiconductor chip including a circuit region and a seal ring region that surrounds the circuit region, and comprising:
a substrate having a top side and a bottom side, and including a well that is formed from the top side of the substrate and that is in the seal ring region, and an isolation element that is formed in the well from the top side of the substrate;
a first seal ring disposed on and connected to the isolation element, and close to an inner boundary of the seal ring region;
a second seal ring disposed on and connected to the well, and close to an outer boundary of the seal ring region;
a first connection feature disposed on and connected to the first seal ring; and
a dielectric structure disposed on the top side of the substrate, and surrounding the first seal ring, the second seal ring and the first connection feature;
wherein at least the first seal ring, the second seal ring, and a portion of the dielectric structure that is disposed between the first seal ring and the second seal ring cooperatively constitute a capacitor.

15. The semiconductor chip according to claim 14, wherein:
each of the first seal ring and the second seal ring includes a plurality of ring features that are arranged from bottom to top; and
a topmost one of the ring features of the first seal ring is higher than a topmost one of the ring features of the second seal ring, and partially overlaps the topmost one of the ring features of the second seal ring.

16. The semiconductor chip according to claim 15, wherein a spacing between the topmost one of the ring features of the first seal ring and the topmost one of the ring features of the second seal ring falls within a range of from 0.01 μm to 5 μm.

17. The semiconductor chip according to claim 14, further comprising a second connection feature that is disposed on and connected to the second seal ring and that is surrounded by the dielectric structure, wherein a first combination of the first seal ring and the first connection feature, a second combination of the second seal ring and the second connection feature, and a portion of the dielectric structure that is disposed between the first combination and the second combination cooperatively constitute the capacitor.

18. The semiconductor chip according to claim 17, wherein an effective spacing between the first combination and the second combination falls within a range of from 2 μm to 5 μm.

19. A method for manufacturing a semiconductor chip, comprising:
preparing a first chip portion that includes
a first substrate,
a first seal ring disposed on the first substrate,
a second seal ring disposed on the first substrate, and
a first interlayer dielectric disposed on the first substrate, and surrounding the first seal ring and the second seal ring;
forming a first dielectric layer and a first bonding element on the first chip portion, where the first bonding element is connected to the first seal ring and is surrounded by the first dielectric layer;
preparing a second chip portion that includes
a second substrate,
a third seal ring disposed on the second substrate, and
a second interlayer dielectric disposed on the second substrate, and surrounding the third seal ring;
forming a second dielectric layer and a second bonding element on the second chip portion, where the second bonding element is connected to the third seal ring and is surrounded by the second dielectric layer;
bonding the first dielectric layer and the second dielectric layer to each other, and bonding the first bonding element and the second bonding element to each other; and
forming a conductive ring in the second substrate and the second interlayer dielectric, where the conductive ring is connected to the third seal ring.

20. The method according to claim 19, further comprising:
thinning down the second substrate before the conductive ring is formed.
